(19) United States
(12) Patent Application Publication
(10) Pub. No.: US 2023/0152916 A1
(43) Pub. Date: May 18, 2023

(54) ELECTRONIC DEVICE HAVING FINGERPRINT SENSING FUNCTION

(71) Applicant: Egis Technology Inc., Hsinchu City (TW)

(72) Inventors: Yao-Li Huang, Hsinchu City (TW); Yu-Hsuan Lin, Hsinchu City (TW); Tzu-Yang Peng, Hsinchu City (TW)

(73) Assignee: Egis Technology Inc., Hsinchu City (TW)

(21) Appl. No.: 17/802,531

(22) PCT Filed: Oct. 23, 2020
(86) PCT No.: PCT/CN2020/123152

§ 371 Date: Aug. 26, 2022

Related U.S. Application Data
(60) Provisional application No. 63/016,990, filed on Apr. 29, 2020.
(60) Provisional application No. 63/021,082, filed on May 6, 2020.

(51) Int. Cl. G06F 3/041; G06V 40/13; H10K 59/131; H10K 59/40; H10K 59/35; G09G 3/3275

(52) U.S. Cl. CPC G06F 3/0416; G06V 40/1318; G06F 3/0412; H10K 59/131; H10K 59/40; H10K 59/351; G09G 3/3275; G09G 2310/027; G09G 2310/08

(57) ABSTRACT

Provided is an electronic device comprising a touch display panel and an integrated chip. The touch display panel comprises a pixel array. The integrated chip is electrically connected to the pixel array. The integrated chip comprises a fingerprint sensing circuit and a display driving circuit. The fingerprint sensing circuit and the display driving circuit are electrically connected to a plurality of display data lines and sensing data lines by means of the same pin. The plurality of display data lines are respectively electrically connected to a plurality of color sub-pixels of the pixel array. The sensing data lines are electrically connected to a plurality of fingerprint sensing pixels of the pixel array. The plurality of color sub-pixels are a plurality of organic light emitting diode pixels.

### TECHNICAL FIELD

The present invention relates to a device, and in particular to an electronic device having a fingerprint sensing function.

### DESCRIPTION OF RELATED ART

In recent years, fingerprint recognition technology has been widely used in various electronic devices to provide various identity login or authentication functions. At present, the technical principles of conventional fingerprint recognition include optical, capacitive, thermal, ultrasonic, etc. In this regard, since a fingerprint sensor for the above manners is disposed in the electronic device, the fingerprint sensor usually needs to occupy a part of the device volume of the electronic device. The general fingerprint sensor may be, for example, disposed or externally mounted under the screen, the home button, the back of the body, etc. of the electronic device. In other words, the general fingerprint sensor increases the overall device volume or thickness of the electronic device, thereby causing an increase in the manufacturing cost of the electronic device. In view of this, solutions of several embodiments will be provided below.

### SUMMARY

The present invention is directed to an electronic device that can provide a large-area fingerprint sensing function.

According to an embodiment of the present invention, an electronic device of the present invention includes a touch display panel and an integrated chip. The touch display panel includes a pixel array. The integrated chip is electrically connected to the pixel array. The integrated chip includes a fingerprint sensing circuit and a display driving circuit. The fingerprint sensing circuit and the display driving circuit are electrically connected to a plurality of display data lines and a sensing data line by means of the same pin. The display data lines are respectively electrically connected to a plurality of color sub-pixels of the pixel array. The sensing data line is electrically connected to a plurality of fingerprint sensing pixels of the pixel array. The color sub-pixels are a plurality of organic light emitting diode pixels.

Based on the above, the electronic device of the present invention can realize the full-screen fingerprint sensing function through forming the fingerprint sensing pixels in the pixel array of the touch display panel, and since the fingerprint sensing pixels are embedded in the touch display panel, the electronic device of the present invention can effectively reduce the functional module space required for fingerprint sensing, thereby reducing the overall device volume or thickness of the electronic device.

In order for the features and advantages of the present invention to be more comprehensible, the following specific embodiments are described in detail in conjunction with the drawings.

### BRIEF DESCRIPTION OF THE DRAWINGS

FIG. 1 is a schematic diagram of an electronic device according to an embodiment of the present invention.

FIG. 2 is a schematic circuit diagram of a part of a pixel array according to an embodiment of the present invention.

FIG. 3 is a schematic circuit diagram of an integrated chip and a switching circuit according to an embodiment of the present invention.

FIG. 4 is a schematic diagram of an internal functional circuit of an integrated chip according to an embodiment of the present invention.

FIG. 5 is a signal timing diagram of a plurality of signals for operating an integrated chip according to an embodiment of the present invention.

### DESCRIPTION OF THE REFERENCE SIGNS

100: electronic device;

110: touch display panel;

120: pixel array;

130: integrated chip;

131: fingerprint sensing circuit;

131_1: amplifier;

131_2: analog-to-digital converter;

131_3: digital processor;

132: display driving circuit;

132_1: source amplifier;

132_2: timing control circuit;

133: control circuit;

141, 142, 143, 144, 145: demultiplexer;

D1-D4, D6: display data line;

D5: sensing data line;

DS: display driving signal;

G1, G2: gate line;

GS1: scanning signal;

FS: sensing signal;

M1-M_5, S1, S2: switching signal;

N1: pin;

T1-T7: transistor;

t0-t6: time.

### DETAILED DESCRIPTION OF DISCLOSED EMBODIMENTS

Reference will now be made in detail to the exemplary embodiments of the present invention, examples of which are illustrated in the drawings. Wherever possible, the same reference numerals are used in the drawings and the description to refer to the same or similar parts.

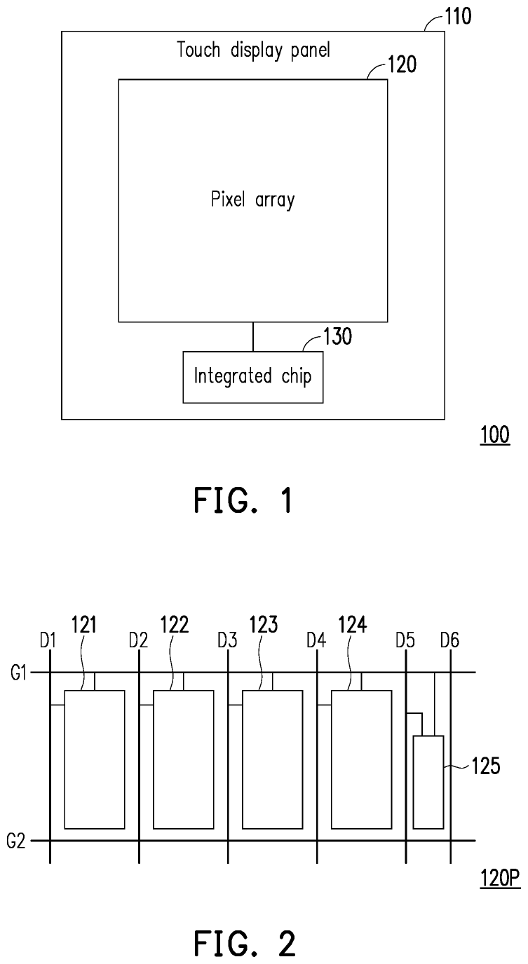

FIG. 1 is a schematic diagram of an electronic device according to an embodiment of the present invention. Referring to FIG. 1, an electronic device 100 includes a touch display panel 110, a pixel array 120, and an integrated chip (IC) 130. The pixel array 120 is electrically connected to the integrated chip 130. In the embodiment, the touch display panel 110 may include, for example, a glass substrate and a touch panel, wherein the pixel array 120 is formed on the glass substrate of an active area (AA) of the touch display panel 110. The integrated chip 130 is formed in a peripheral area (PA) of the touch display panel 110. In the embodiment, the integrated chip 130 includes a fingerprint sensing circuit 131 and a display driving circuit 132. It should be noted that the touch display panel 110 of the embodiment may adopt an in-cell fingerprint, touch, and display panel structure. The integrated chip 130 may be a fingerprint, touch, and display driver integrated (FTDDI) chip.

In the embodiment, the integrated chip 130 may be electrically connected to a plurality of display pixels and a plurality of fingerprint sensing pixels in the pixel array 120 by means of the same pin, and the integrated chip 130 drives a display module of the touch display panel 110 and the touch display panel 110 in a time-sharing manner. In other words, the integrated chip 130 of the embodiment may drive the display module and a fingerprint sensing module in the touch display panel 110 through fewer pins, thereby effectively reducing the space occupied by the pins and wiring in the electronic device 100.

In the embodiment, the electronic device 100 is, for example, a smart phone, a tablet computer, a game console, or other electronic products having a fingerprint recognition function. The touch display panel 110 may include, for example, an organic light emitting diode (OLED) display panel, so a plurality of color sub-pixels of a plurality of pixel units of the pixel array 120 are a plurality of organic light emitting diode pixel units. In detail, in the embodiment, the pixel units of the pixel array 120 may be composed of a plurality of first color sub-pixels, a plurality of second color sub-pixels, a plurality of third color sub-pixels, and a plurality of fingerprint sensing pixels. The first to third color sub-pixels may be, for example, red color sub-pixels, green color sub-pixels, and blue color sub-pixels, but the present invention is not limited thereto. In an embodiment, the pixel units of the pixel array 120 may further include a plurality of fourth color sub-pixels, wherein the fourth color sub-pixels may be, for example, white color sub-pixels, but the present invention is not limited thereto. It should be noted that in the embodiment, the color sub-pixels may be formed on a first semiconductor layer of the touch display panel 110, and the fingerprint sensing pixels may be formed on a second semiconductor layer of the touch display panel 110.

FIG. 2 is a schematic circuit diagram of a part of a pixel array according to an embodiment of the present invention. Referring to FIG. 1 and FIG. 2, a pixel unit 120P of FIG. 2 is a configuration result of one pixel in the pixel array 120. In the embodiment, the pixel unit 120P includes a first color sub-pixel 121, a second color sub-pixel 122, a third color sub-pixel 123, a fourth color sub-pixel 124, and a fingerprint sensing pixel 125. The first color sub-pixel 121, the second color sub-pixel 122, the third color sub-pixel 123, the fourth color sub-pixel 124, and the fingerprint sensing pixel 125 are electrically connected to a gate line G1. A gate line G2 is used to electrically connect to the next column of pixel units, and so on. The first color sub-pixel 121 to the fourth color sub-pixel 124 are respectively electrically connected to display data lines D1 to D4. The fingerprint sensing pixel 125 is electrically connected to a sensing data line D5. A display data line D6 is used to electrically connect to the next row of sub-pixels, and so on.

In the embodiment, the gate line G1 may be used to receive a scanning signal to turn on the first color sub-pixel 121, the second color sub-pixel 122, the third color sub-pixel 123, the fourth color sub-pixel 124, and the fingerprint sensing pixel 125. In the embodiment, the display data lines D1 to D4 are used to transmit a plurality of display driving signals (display data) provided by the integrated chip 130 to the first color sub-pixel 121, the second color sub-pixel 122, the third color sub-pixel 123, and the fourth color sub-pixel 124, so that the first color sub-pixel 121, the second color sub-pixel 122, the third color sub-pixel 123, and the fourth color sub-pixel 124 respectively provide a display function according to the corresponding display driving signals (display data). In the embodiment, the sensing data line D5 is used to transmit a sensing signal of the fingerprint sensing pixel 125 to the integrated chip 130, so that the integrated chip 130 may generate a corresponding fingerprint sensing image according to the sensing signal. The arrangement order of the color sub-pixels of the present invention is not limited to the above. Moreover, the placement location of the fingerprint sensing pixel 125 may also be set between any two color sub-pixels.

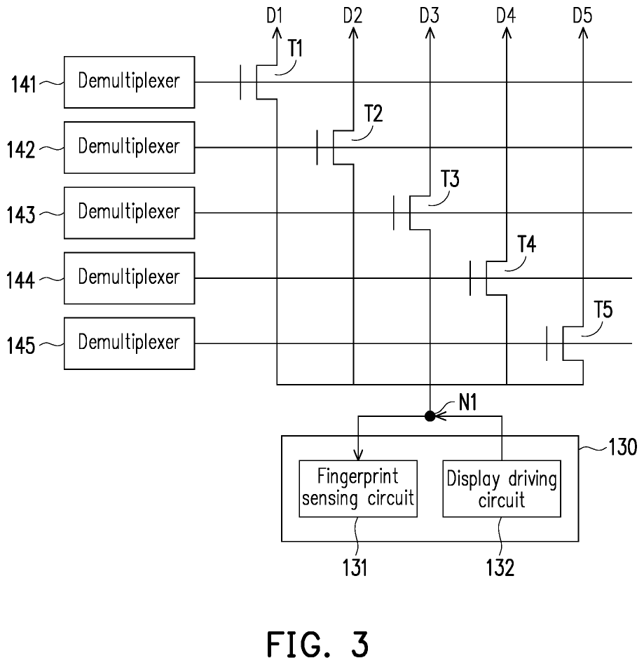

FIG. 3 is a schematic circuit diagram of an integrated chip and a switching circuit according to an embodiment of the present invention. Referring to FIG. 1 to FIG. 3, the integrated chip 130 includes the fingerprint sensing circuit 131 and the display driving circuit 132. In the embodiment, the fingerprint sensing circuit 131 and the display driving circuit 132 are electrically connected to one terminal of switch transistors T1 to T5 by means of a same pin N1 (that is, forming a common pin), and the other terminals of the switch transistors T1 to T5 are electrically connected to the display data lines D1 to D4 and the sensing data line D5. Control terminals of the switch transistors T1 to T5 are respectively electrically connected to demultiplexers (DMUX) 141 to 145. In the embodiment, the demultiplexers 141 to 145 output switching signals at different timings to the switch transistors T1 to T5 to receive signals from the color sub-pixels 121 to 124 or the fingerprint sensing pixel 125 during different periods. The demultiplexers 141 to 145 may be respectively composed of one or more transistors or switch circuits, and the demultiplexers 141 to 145 may form a demultiplexer circuit.

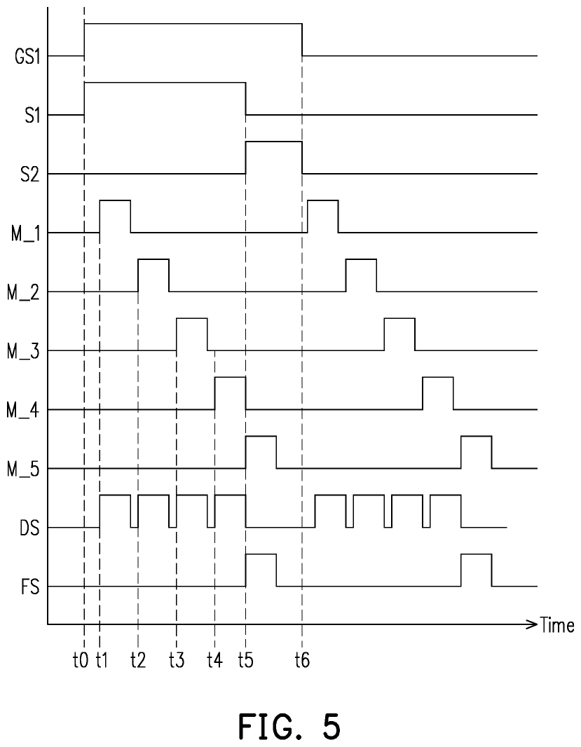

In the embodiment, the display data lines D1 to D4 and the sensing data line D5 are electrically connected to a row pixel group of the pixel array 120, wherein the row pixel group may include a plurality of pixel units 120P as in the above embodiment of FIG. 2 arranged in sequence along the data line. In other words, the fingerprint sensing circuit 131 and the display driving circuit 132 of the integrated chip 130 provide a plurality of data signals to a plurality of color sub-pixels in the row pixel group electrically connected to the display data lines D1 to D4 by means of the same pin N1, and receive sensing results of a plurality of fingerprint sensing pixels in the row pixel group through the sensing data line D5. However, in an embodiment, the pin N1 may also be electrically connected to other row pixel groups in the pixel array 120, or the integrated chip 130 may be electrically connected to other row pixel groups in the pixel array 120 by means of other pins similar to the pin N1. In addition, the timings of the switching signals, the display driving signals, and the sensing signal of the embodiment will be described in detail with reference to the embodiment of FIG. 5 below.

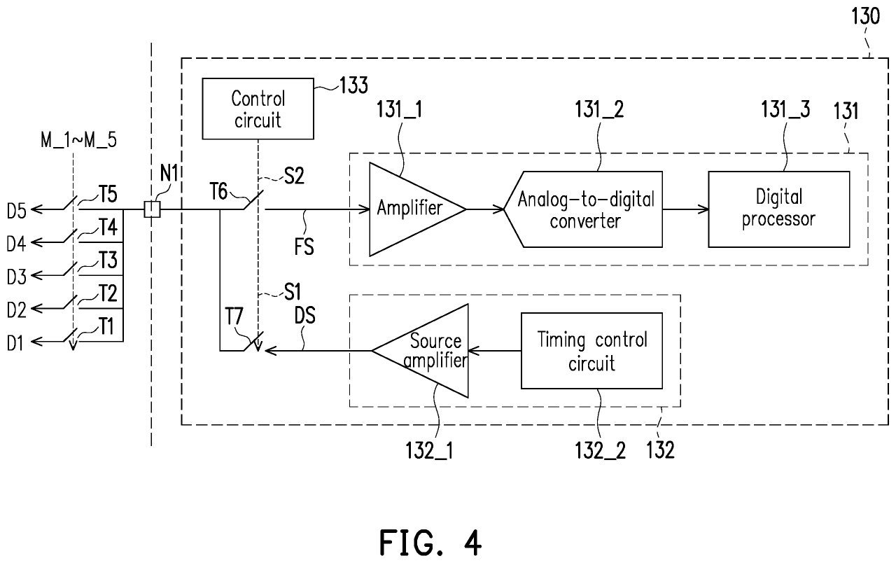

FIG. 4 is a schematic diagram of an internal functional circuit of an integrated chip according to an embodiment of the present invention. Referring to FIG. 4, the integrated chip 130 includes the fingerprint sensing circuit 131, the display driving circuit 132, and a control circuit 133. In the embodiment, the control circuit 133 is electrically connected between the pin N1 and the fingerprint sensing circuit 131 by means of a first switching circuit, and is electrically connected between the pin N1 and the display driving circuit 132 by means of a second switching circuit. The control circuit is used to alternately turn on the first switching circuit and the second switching circuit. In the embodiment, the first switching circuit may be a switch transistor T6, and the second switching circuit may be a switch transistor T7, but the present invention is not limited thereto. One terminal of the switch transistor T6 is electrically connected to the pin N1, and one terminal of the switch transistor T7 is electrically connected to the pin N1 and one terminal of the switch transistor T6. Control terminals of the switch transistor T6 and the switch transistor T7 are electrically connected to the control circuit 133. The control circuit 133 may output two switching signals Si and S2 to the switch transistor T6 and the switch transistor T7 to control the switch transistor T6 and the switch transistor T7.

In the embodiment, the fingerprint sensing circuit 131 includes an amplifier 131_1, an analog-to-digital converter 131_2, and a digital processor 131_3. An input terminal of the amplifier 131_1 is electrically connected to the other terminal of the switch transistor T6. An input terminal of the analog-to-digital converter 131_2 is electrically connected to an output terminal of the amplifier 131_1. The digital processor 131_3 is electrically connected to an output terminal of the analog-to-digital converter 131_2. In the embodiment, the display driving circuit 132 includes a source amplifier 132_1 and a timing control circuit 132_2. An input terminal of the source amplifier 132_1 is electrically connected to the timing control circuit 132_2, and an output terminal of the source amplifier 132_1 is electrically connected to the other terminal of the switch transistor T7. In the embodiment, the pin N1 is electrically connected to the switch transistors T1 to T5 on one side opposite to the pin N1. The switch transistors T1 to T5 are electrically connected to the display data lines D1 to D4 and the sensing data line D5.

In the embodiment, the amplifier 131_1 may receive the sensing signal and provide a sensing signal FS after signal amplification to the analog-to-digital converter 131_2. The analog-to-digital converter 131_2 may provide a digital signal of a fingerprint sensing result to the digital processor 131_3, so that the digital processor 131_3 may generate fingerprint sensing information, for example, generate a fingerprint sensing image, according to the digital signal provided by the analog-to-digital converter 131_2. In the embodiment, the timing control circuit 132_2 of the display driving circuit 132 may provide the timing control signal to the source amplifier 132_1, so that the source amplifier 132_1 outputs a display driving signal DS according to the designed display timing.

FIG. 5 is a signal timing diagram of a plurality of signals for operating an integrated chip according to an embodiment of the present invention. Referring to FIG. 2 to FIG. 5, a time t0 to a time t6 are a driving period of the pixel unit 120P (or the driving period of one row pixel group), wherein the driving period includes a display driving period and a fingerprint sensing period, and the display driving period and the fingerprint sensing period do not overlap. For example, the display driving period is from the time t0 to the time t5. The fingerprint sensing period is from the time t5 to the time t6. In an embodiment, the color sub-pixels 121 to 124 and the fingerprint sensing pixel 125 of the pixel unit 120P receive a scanning signal GS1 by means of the gate line G1, and are turned on from the time t0 to the time t5. In the embodiment, the switch transistor T7 receives the switching signal S1, and the switch transistor T6 receives the switching signal S2. The switch transistors T1 to T5 respectively receive switching signals M_1 to M_5 respectively provided by the demultiplexers 141 to 145.

In the embodiment, the switch transistor T6 is turned off during the display driving period (the time t0 to the time t5), and the switch transistor T7 is turned on during the display driving period (the time t0 to the time t5). During the display driving period, the display driving period includes four sub-display driving periods, wherein the four sub-display driving periods are respectively from the time t1 to the time t2, from the time t2 to the time t3, from the time t3 to the time t4, and from the time t4 to the time t5. The switch transistors T1 to T4 respectively receive the switching signals M_1 to M_4 during the four sub-display driving periods and are turned on during different periods, and the switch transistor T5 is turned off. Signal waveforms of the switching signals M_1 to M_4 do not overlap in time. Therefore, during the four sub-display driving periods, the display driving circuit 132 respectively outputs first to fourth display driving signals (square waveforms of the display driving signal DS during the four sub-display driving periods as shown in FIG. 5) to the display data lines D1 to D4 by means of the pin N1 during different periods.

In this regard, during the display driving period, the display driving circuit 132 may output the display driving signal DS to the color sub-pixels 121 to 124 by means of the display data lines D1 to D4, so that the pixel unit 120P performs the display function. However, it should be noted that the display driving signal DS of FIG. 5 only represents the timing relationship of the signal waveforms, instead of the actual signal waveforms. In this regard, the voltage level or the potential level of the display data of the display driving signal DS may be determined by different display effects or individual sub-pixel types, which is not limited by the present invention.

In the embodiment, the switch transistor T5 is turned on during the fingerprint sensing period (the time t5 to the time t6), and the switch transistor T6 is turned off during the fingerprint sensing period (the time t5 to the time t6). During the fingerprint sensing period, the switch transistors T1 to T4 are turned off, and the switch transistor T5 is turned on. The signal waveform of the switching signal M_5 and the signal waveforms of the switching signals M_1 to M_4 do not overlap. Therefore, the fingerprint sensing circuit 131 may receive the sensing signal FS from the fingerprint sensing pixel 125 by means of the sensing data line D5, so that the pixel unit 120P performs the fingerprint sensing function. However, it should be noted that the sensing signal FS of FIG. 5 only represents the timing relationship of the signal waveforms, instead of the actual signal waveforms. In this regard, the voltage level or the potential level of the sensing data of the sensing signal FS may be determined by different sensing results.

In summary, the electronic device of the present invention implements an in-cell fingerprint, touch, and display panel structure, and uses the fingerprint, touch, and display driver integrated chip to drive the touch display panel embedded with the fingerprint sensing pixels. Therefore, the electronic device of the present invention can save the space occupied by the driving circuit in the peripheral area of the panel. Alternatively, the integrated chip of the present invention may transmit the display driving signal and the sensing signal by means of the same pin, which can effectively save the space occupied by the pins and wiring in the peripheral area of the panel.

Finally, it should be noted that the above embodiments are only used to illustrate, but not to limit, the technical solutions of the present invention. Although the present invention has been described in detail with reference to the above embodiments, persons skilled in the art should understand that the technical solutions described in the above embodiments can still be modified or some or all of the technical features thereof can be equivalently replaced. However, the modifications or replacements do not cause the essence of the corresponding technical solutions to deviate from the scope of the technical solutions of the embodiments of the present invention.

What is claimed is:

1. An electronic device, comprising:
a touch display panel, comprising a pixel array; and
an integrated chip, electrically connected to the pixel array and comprising a fingerprint sensing circuit and a display driving circuit,
wherein the fingerprint sensing circuit and the display driving circuit are electrically connected to a plurality of display data lines and a sensing data line by means of a same pin,
wherein the display data lines are electrically connected to a plurality of color sub-pixels of the pixel array, and the sensing data line is respectively electrically connected to a plurality of fingerprint sensing pixels of the pixel array, wherein the color sub-pixels are a plurality of organic light emitting diode pixels.

2. The electronic device according to claim 1, wherein the pin is electrically connected to the display data lines by means of a plurality of transistors, and the pin is electrically connected to the sensing data line by means of another transistor.

3. The electronic device according to claim 2, wherein control terminals of the transistors respectively receive a plurality of switching signals, and signal waveforms of the switching signals do not overlap in time.

4. The electronic device according to claim 1, wherein the display driving circuit outputs a plurality of display driving signals by means of the pin during a display driving period to drive the color sub-pixels, and the fingerprint sensing circuit receives sensing signals of the fingerprint sensing pixels by means of the pin during a fingerprint sensing period, wherein the display driving period and the fingerprint sensing period do not overlap.

5. The electronic device according to claim 4, wherein the display driving period comprises a plurality of sub-display driving periods, and during the sub-display driving periods, the display driving circuit respectively outputs the display driving signals to the display data lines by means of the pin at different times.

6. The electronic device according to claim 1, wherein the integrated chip further comprises:
a first switching circuit, having one terminal electrically connected to the pin and having other terminal electrically connected to the fingerprint sensing circuit;
a second switching circuit, having one terminal electrically connected to the pin and having other terminal electrically connected to the display driving circuit; and
a control circuit, electrically connected to the first switching circuit and the second switching circuit, wherein the control circuit alternately turns on the first switching circuit and the second switching circuit.

7. The electronic device according to claim 6, wherein the fingerprint sensing circuit comprises:
an amplifier, having an input terminal electrically connected to the other terminal of the first switching circuit;
an analog-to-digital converter, having an input terminal electrically connected to an output terminal of the amplifier; and
a digital processor, electrically connected to an output terminal of the analog-to-digital converter.

8. The electronic device according to claim 6, wherein the display driving circuit comprises:
a timing control circuit; and
a source amplifier, having an input terminal electrically connected to the timing control circuit and having an output terminal electrically connected to the other terminal of the second switching circuit.

9. The electronic device according to claim 1, wherein the color sub-pixels are formed on a first semiconductor layer of the touch display panel, and the fingerprint sensing pixels are formed on a second semiconductor layer of the touch display panel.

10. The electronic device according to claim 1, wherein the color sub-pixels comprise at least one red sub-pixel, at least one green sub-pixel, and at least one blue sub-pixel.

11. The electronic device according to claim 1, wherein the color sub-pixels comprise at least one red sub-pixel, at least one green sub-pixel, at least one blue sub-pixel, and at least one white sub-pixel.

12. The electronic device according to claim 1, wherein the integrated chip further comprises a touch driving circuit.
